(19) United States
(12) Patent Application Publication
(10) Pub. No.: US 2026/0353884 A1
(43) Pub. Date: Nov. 5, 2026

(54) Display Device

(71) Applicant: LG Display Co., Ltd., Seoul (KR)

(72) Inventors: SangHoon Lee, Seoul (KR); KwangSu Lim, Seoul (KR); TaeYong Kim, Gwangmyeong-si (KR); Junhyeok Lee, Seoul (KR)

(21) Appl. No.: 19/630,222

(22) Filed: Mar. 26, 2026

(30) Foreign Application Priority Data
Apr. 30, 2025 (KR) 10-2025-0056906

(51) Int. Cl. H10H 29/41; H10H 20/831; H10H 29/49

(52) U.S. Cl. CPC H10H 29/41; H10H 20/8312; H10H 29/49

(57) ABSTRACT

A display device presented herein includes a substrate on which a plurality of sub pixels is defined, a plurality of first assembly electrodes, a plurality of second assembly electrodes disposed in each of the plurality of sub pixels and spaced apart from the plurality of first assembly electrodes, a first insulating layer disposed on the plurality of first assembly electrodes and the plurality of second assembly electrodes and including a plurality of pockets overlapping the plurality of sub pixels, and a plurality of light emitting elements disposed in the plurality of pockets of the first insulating layer. Each of the plurality of pockets overlaps a vertex of the plurality of first assembly electrodes and a vertex of the plurality of second assembly electrodes. The light emitting element is assembled in an area having high dielectrophoresis force to improve an assembly yield of the light emitting element.

### CROSS-REFERENCE TO RELATED APPLICATION

This application claims priority to Republic of Korea Patent Application No. 10-2025-0056906, filed on Apr. 30, 2025, which is incorporated herein by reference in its entirety.

### TECHNICAL FIELD

The present disclosure relates to a display device, and more particularly, to a display device using a light emitting diode (LED).

### BACKGROUND

Display devices used for a monitor of a computer, a TV, or a mobile phone include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

In addition, recently, a display device including an LED is attracting attention as a next-generation display device. Since the LED is made of an inorganic material rather than an organic material, reliability is excellent, and a lifespan thereof is longer than that of a liquid crystal display device or an organic light emitting display device. Further, the LED has a fast lighting speed, excellent luminous efficiency, and a strong impact resistance so that a stability is excellent and an image having a high luminance can be displayed.

### SUMMARY

An object to be achieved by the present disclosure is to provide a display device in which a light emitting element is assembled in an area having high dielectrophoresis (DEP) force.

Another object to be achieved by the present disclosure is to provide a display device with an improved assembly yield of a light emitting element.

Still another object to be achieved by the present disclosure is to provide a display device in which an assembly resolution of a light emitting element is increased.

Objects of the present disclosure are not limited to the above-mentioned objects, and other objects, which are not mentioned above, can be clearly understood by those skilled in the art from the following descriptions.

According to one or more embodiments of the present disclosure, a display device includes a substrate on which a plurality of sub pixels is defined, a plurality of first assembly electrodes and a plurality of second assembly electrodes disposed in each of the plurality of sub pixels, the plurality of second assembly electrodes are disposed to be spaced apart from the plurality of first assembly electrodes, a first insulating layer disposed on the plurality of first assembly electrodes and the plurality of second assembly electrodes and including a plurality of pockets overlapping the plurality of sub pixels, and a plurality of light emitting elements disposed in the plurality of pockets of the first insulating layer, each of the plurality of pockets overlaps a vertex of the plurality of first assembly electrodes and a vertex of the plurality of second assembly electrodes.

A display device according to one or more other embodiments of the present disclosure includes a substrate on which a plurality of sub pixels is defined, a plurality of first assembly electrodes and a plurality of second assembly electrodes disposed in each of the plurality of sub pixels, the plurality of second assembly electrodes are disposed to be spaced apart from the plurality of first assembly electrodes, a first insulating layer disposed on the plurality of first assembly electrodes and the plurality of second assembly electrodes and including a plurality of pockets overlapping the plurality of sub pixels, and a plurality of light emitting elements disposed in the plurality of pockets of the first insulating layer, wherein a planar shape of each of the plurality of pockets encloses one vertex of the vertices of the plurality of first assembly electrodes and one vertex of the vertices of the plurality of second assembly electrodes.

Other detailed matters of the embodiments are included in the detailed description and the drawings.

According to the present disclosure, it is possible to improve the assembly yield of the light emitting element and achieve process optimization by assembling the light emitting element in an area having high dielectrophoresis force.

According to the present disclosure, it is possible to prevent a problem in which several light emitting elements are assembled in one pocket.

According to the present disclosure, it is possible to improve the assembly resolution by increasing the number of light emitting elements that may be assembled by using a pair of assembly electrodes.

The effects according to the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a schematic plan view of a display device according to one or more embodiments of the present disclosure.

FIG. 2 is an enlarged plan view of a display device according to one or more embodiments of the present disclosure.

FIG. 3 is a cross-sectional view taken along line A-A' in FIG. 2.

FIG. 4 is an enlarged plan view of a display device according to one or more other embodiments of the present disclosure.

FIG. 5 is an enlarged plan view of a display device according to still one or more other embodiments of the present disclosure.

FIG. 6 is an enlarged plan view of a display device according to still one or more other embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” “comprising,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to the drawings.

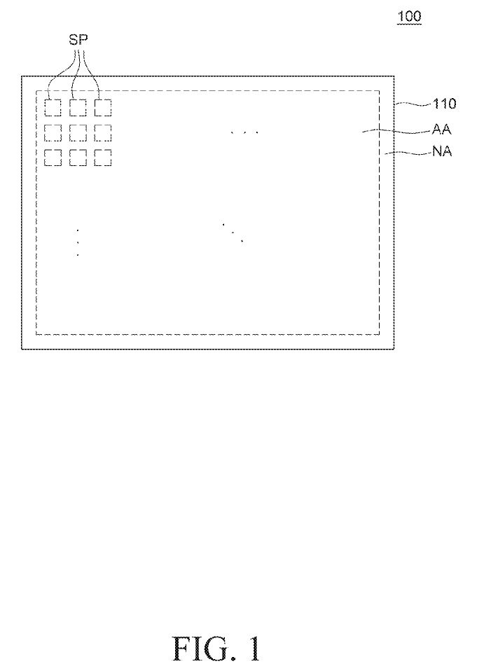

FIG. 1 is a schematic plan view of a display device according to one or more embodiments of the present disclosure. In FIG. 1, for the convenience of description, among various components of the display device 100, only a substrate 110 is illustrated.

Referring to FIG. 1, the substrate 110 is a component for supporting various components included in the display device 100 and may be formed of an insulating material. For example, the substrate 110 may be made of glass, resin, or the like. Further, the substrate 110 may be made of polymer, plastic, or the like, and in some embodiments, the substrate 110 may be made of a plastic material having flexibility. A plurality of sub pixels SP may be formed on the substrate 110 to display an image.

The display area AA and the non-display area NA may be defined in the substrate 110.

The display area AA is an area in which images are displayed in the display device 100. A plurality of sub pixels SP may be disposed in the display area AA. The plurality of sub pixels SP is a minimum unit constituting the display area AA, and may include a plurality of light emitting elements to emit light. The plurality of sub pixels SP may display light of various colors, such as red light, green light, and blue light, and may display images of various colors by a combination thereof. The plurality of light emitting elements may be differently defined depending on the type of the display device 100. For example, when the display device 100 is an inorganic light emitting display device 100, the light emitting element may be a light emitting element (LED) or a micro light emitting element (micro-LED).

In the display area AA, a plurality of signal lines for transmitting various signals to the plurality of sub pixels SP is disposed. For example, the plurality of signal lines may include a plurality of power lines and the like which supplies a power voltage to each of the plurality of sub pixels SP.

The non-display area NA is an area where an image is not displayed and may be defined as an area extending from the display area AA. In the non-display area NA, a link line, a pad electrode, or a driving IC for transmitting a signal to the sub pixel SP of the display area AA may be disposed. Meanwhile, the non-display area NA may be located on a rear surface of the display device 100, that is, a surface on which the sub pixels SP are not disposed or may be omitted, and is not limited to the configuration illustrated in the drawings.

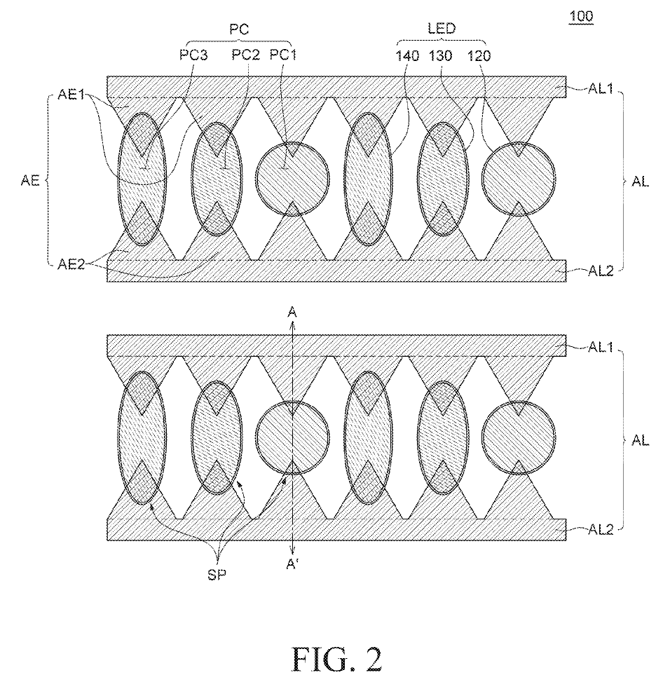

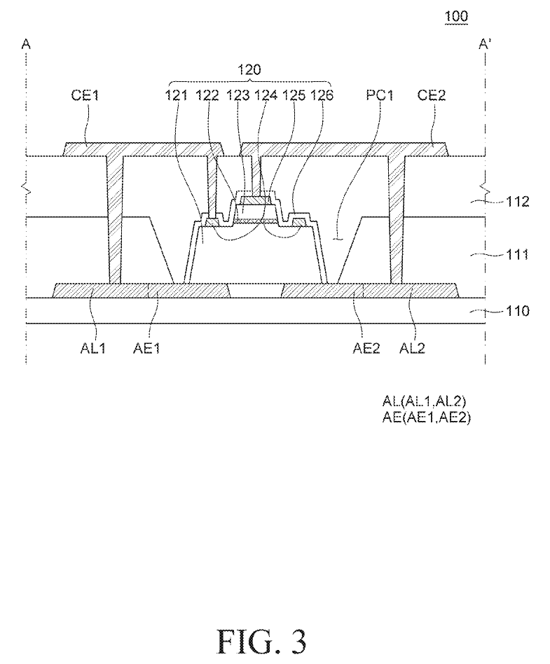

FIG. 2 is an enlarged plan view of a display device according to one or more embodiments of the present disclosure. FIG. 3 is a cross-sectional view taken along line A-A' in FIG. 2. FIG. 2 is a cross-sectional view of a sub pixel SP in which a first light emitting element 120 is disposed among a plurality of light emitting elements LED. In FIG. 2, the second light emitting element 130 and the third light emitting element 140 are substantially identical in configuration to the first light emitting element 120 except for a color and a planar shape. Therefore, redundant description thereof will be omitted. Further, in FIG. 2, for the convenience of description, only an area corresponding to a total of 12 sub pixels SP is illustrated, and in the display device 100, the area illustrated in FIG. 2 may be repeatedly disposed.

Referring to FIGS. 2 and 3, the display device 100 includes a substrate 110, a first insulating layer 111, a second insulating layer 112, a plurality of light emitting elements LED, a plurality of assembly lines AL, a plurality of assembly electrodes AE, a first connection electrode CE1, and a second connection electrode CE2.

First, a plurality of assembly lines AL is disposed on the substrate 110. The plurality of assembly lines AL are lines which generate an electric field for self-assembling the plurality of light emitting elements LED when the display device 100 is manufactured and supply a driving voltage to the plurality of light emitting elements LED when the display device 100 is driven. The plurality of assembly lines AL may be disposed along the plurality of sub pixels SP disposed in the same line. The plurality of assembly lines AL may be disposed to overlap the plurality of sub pixels SP disposed in the same column. For example, the first assembly line AL1 and the second assembly line AL2 may be disposed along the plurality of sub pixels SP disposed in the same column.

The plurality of assembly lines AL includes a plurality of first assembly lines AL1 and a plurality of second assembly lines AL2. The plurality of first assembly lines AL1 and the plurality of second assembly lines AL2 may be alternately disposed. The plurality of first assembly lines AL1 and the plurality of second assembly lines AL2 may be disposed to be spaced apart from each other with a predetermined interval. In each of the plurality of sub pixels SP, one first assembly line AL1 and one second assembly line AL2 may be disposed adjacent to each other. When the display device 100 is driven, different driving voltages are applied to the plurality of first assembly lines AL1 and the plurality of second assembly lines AL2 to drive the plurality of light emitting elements LED in a passive matrix (PM) manner.

If the plurality of light emitting elements LED is driven in a passive matrix manner, the display device 100 may be used for a lighting device or the like. For example, the display device 100 may be used as a lighting device capable of displaying various colors and illuminance by turning on or off all or a part of the plurality of light emitting elements LED. The display device 100 is not limited thereto, and may further include a driving element such as a driving transistor to be driven in an active matrix (AM) manner.

The plurality of assembly electrodes AE is disposed in each of the plurality of sub pixels SP on the substrate 110. The plurality of assembly electrodes AE includes a plurality of first assembly electrodes AE1 and a plurality of second assembly electrodes AE2. The plurality of first assembly electrodes AE1 may be connected to the plurality of first assembly lines AL1, and the plurality of second assembly electrodes AE2 may be connected to the plurality of second assembly lines AL2. For example, the plurality of first assembly electrodes AE1 may be integrally formed with the plurality of first assembly lines AL1, and the plurality of second assembly electrodes AE2 may be integrally formed with the plurality of second assembly lines AL2, but is not limited thereto. The plurality of assembly lines AL and the plurality of assembly electrodes AE may be formed of the same material on the same plane, but are not limited thereto.

The pair of first assembly electrodes AE1 and the second assembly electrode AE2 may be disposed adjacent to each other to form an electric field for self-assembling the light emitting element LED. Each of the pair of first assembly electrodes AE1 and second assembly electrodes AE2 may be disposed to overlap a position where the light emitting element LED is disposed in the plurality of sub pixels SP.

Planar shapes of the plurality of first assembly electrodes AE1 and the plurality of second assembly electrodes AE2 may be triangular. Therefore, the widths of the plurality of first assembly electrodes AE1 and the plurality of second assembly electrodes AE2 may be gradually changed. For example, the width of the first assembly electrode AE1 may decrease as it approaches the second assembly electrode AE2, and the width of the second assembly electrode AE2 may decrease as it approaches the first assembly electrode AE1. In addition, one side of the three sides constituting one first assembly electrode AE1 may be in contact with the first assembly line AL1, and the other two sides may extend from the first assembly line AL1. In addition, one side of the three sides constituting one second assembly electrode AE2 may be in contact with the second assembly line AL2, and the other two sides may extend from the second assembly line AL2.

The plurality of first assembly electrodes AE1 and the plurality of second assembly electrodes AE2 may be disposed to face each other. For example, the plurality of first assembly electrodes AE1 may be disposed in the same column as the plurality of second assembly electrodes AE2. Further, a vertex of the first assembly electrode AE1 and a vertex of the second assembly electrode AE2 may face each other on the same line.

By applying a voltage to the plurality of assembly lines AL and the plurality of assembly electrodes AE, the plurality of light emitting elements LED may be self-assembled in the pockets PC of each of the plurality of sub pixels SP. For example, an AC voltage is applied to the plurality of first assembly lines AL1 and the plurality of first assembly electrodes AE1, the plurality of second assembly lines AL2, and the plurality of second assembly electrodes AE2 to form an electric field. The light emitting element LED is dielectrically polarized by the electric field to have a polarity. Further, the dielectrically polarized light emitting element LED may be moved or fixed in a specific direction by dielectrophoresis (DEP), that is, an electric field. Accordingly, the plurality of light emitting elements LED may be self-assembled inside the pockets PC of the plurality of sub pixels SP by using dielectrophoresis.

The plurality of assembly lines AL and the plurality of assembly electrodes AE may be formed of a conductive material, such as copper (Cu), chromium (Cr), molybdenum (Mo), or titanium molybdenum (MoTi) alloy, but are not limited thereto. Further, the plurality of assembly lines AL and the plurality of assembly electrodes AE may be formed of a plurality of conductive layers. For example, the plurality of assembly lines AL and the plurality of assembly electrodes AE may have a multilayer structure including a conductive layer having a relatively excellent conductivity and a clad layer disposed to cover the conductive layer and having relatively resistant to corrosion, but are not limited thereto.

In the meantime, even though in FIG. 3, it is illustrated that the thicknesses of the plurality of assembly lines AL and the plurality of assembly electrodes AE are the same, it may not be limited thereto. For example, in order to lower the line resistance of the plurality of assembly lines AL, the thickness of the plurality of assembly lines AL may be thicker than the thickness of the plurality of assembly electrodes AE. Accordingly, a voltage may be more easily applied from the plurality of assembly lines AL to the plurality of assembly electrodes AE.

The first insulating layer 111 is disposed on the plurality of assembly lines AL and the plurality of assembly electrodes AE. The first insulating layer 111 may be disposed to cover the entire surface of the substrate 110 on which the plurality of assembly lines AL and the plurality of assembly electrodes AE are formed. The first insulating layer 111 may be configured as a single layer or multilayer made of an organic insulating material, for example, benzocyclobutene or an acrylic organic material, but is not limited thereto.

The first insulating layer 111 may include a plurality of pockets PC. The plurality of pockets PC are openings in which the plurality of light emitting elements LED is self-assembled. Each of the plurality of pockets PC may be formed at a position corresponding to each of the plurality of sub pixels SP. The plurality of pockets PC may be disposed to overlap an area between the pair of first assembly electrodes AE1 and the second assembly electrode AE2. The plurality of pockets PC may be respectively disposed to correspond to the plurality of sub pixels SP one to one. At least any one of the first assembly electrode AE1 and the second assembly electrode AE2 may be exposed from each of the plurality of pockets PC. For example, both the first assembly electrode AE1 and the second assembly electrode AE2 may overlap the pocket PC.

Each of the plurality of pockets PC may include a plurality of first pockets PC1, a plurality of second pockets PC2, and a plurality of third pockets PC3. The shape of each of the plurality of pockets PC may correspond to the shape of the plurality of light emitting elements LED. For example, a planar shape of each of the plurality of first pockets PC1 may correspond to a planar shape of the first light emitting element 120, a planar shape of each of the plurality of second pockets PC2 may correspond to a planar shape of the second light emitting element 130, and a planar shape of each of the plurality of third pockets PC3 may correspond to a planar shape of the third light emitting element 140. For example, the plurality of first pockets PC1 may have a circular planar shape, the plurality of second pockets PC2 may have an oval planar shape, and the plurality of third pockets PC3 may have an oval planar shape different from the plurality of second pockets PC2. Therefore, each of the plurality of first pockets PC1, the plurality of second pockets PC2, and the plurality of third pockets PC3 may have a different shape.

The first pocket PC1, the second pocket PC2, and the third pocket PC3 may be sequentially disposed along a direction in which the first assembly line AL1 and the second assembly line AL2 extend.

Meanwhile, the major axis direction of the plurality of second pockets PC2 may be parallel to the major axis direction of the plurality of third pockets PC3. For example, the major axis direction of the plurality of second pockets PC2 and the major axis direction of the plurality of third pockets PC3 may intersect a direction in which the plurality of assembly lines AL extend.

Each of the plurality of pockets PC may overlap a vertex of the plurality of first assembly electrodes AE1 and a vertex of the plurality of second assembly electrodes AE2. For example, a planar shape of each of the plurality of pockets PC may be a shape surrounding a vertex of the first assembly electrode AE1 and a vertex of the second assembly electrode AE2.

The plurality of light emitting elements LED is disposed in each of the plurality of pockets PC.

Each of the plurality of light emitting elements LED may include a plurality of first light emitting elements 120, a plurality of second light emitting elements 130, and a plurality of third light emitting elements 140. For example, when the light emitting element LED is self-assembled, the light emitting element LED may be self-assembled at a position corresponding to each of the plurality of sub pixels SP by using the plurality of light emitting elements LED having different shapes. Specifically, the plurality of first light emitting elements 120 may have a circular planar shape, the plurality of second light emitting elements 130 may have an oval planar shape, and the plurality of third light emitting elements 140 may have an oval planar shape different from that of the plurality of second light emitting elements 130. However, the shapes of the plurality of light emitting elements LED are exemplary, but are not limited thereto.

The first light emitting element 120, the second light emitting element 130, and the third light emitting element 140 may be sequentially disposed along a direction in which the first assembly line AL1 and the second assembly line AL2 extend.

Meanwhile, the major axis direction of the plurality of second light emitting elements 130 and the major axis direction of the plurality of third light emitting elements 140 may be parallel to each other. For example, the major axis direction of the plurality of second light emitting elements 130 and the major axis direction of the plurality of third light emitting elements 140 may intersect a direction in which the plurality of assembly lines AL extend.

Each of the plurality of light emitting elements LED may overlap a vertex of the plurality of first assembly electrodes AE1 and a vertex of the plurality of second assembly electrodes AE2. For example, the planar shape of each of the plurality of light emitting elements LED may be a circular and/or oval shape surrounding the vertex of the first assembly electrode AE1 and the vertex of the second assembly electrode AE2.

Each of the light emitting elements LED may include a first semiconductor layer, an emission layer, a second semiconductor layer, a first electrode, a second electrode, and an encapsulation layer.

For example, referring to FIG. 3, the first light emitting element 120 includes a first semiconductor layer 121, an emission layer 122, a second semiconductor layer 123, a first electrode 124, a second electrode 125, and an encapsulation layer 126.

First, the first semiconductor layer 121 is disposed on the plurality of assembly electrodes AE, and the second semiconductor layer 123 is disposed on the first semiconductor layer 121. The first semiconductor layer 121 and the second semiconductor layer 123 may be semiconductor layers doped with n-type and p-type impurities. For example, each of the first semiconductor layer 121 and the second semiconductor layer 123 may be a semiconductor layer doped with n-type and p-type impurities into a material such as gallium nitride (GaN), indium aluminum phosphide (InAlP), or gallium arsenide (GaAs), etc. Further, the p-type impurity may be magnesium (Mg), zinc (Zn), beryllium (Be), and the like, and the n-type impurity may be silicon (Si), germanium, tin (Sn), and the like, but not limited thereto.

The emission layer 122 is disposed between the first semiconductor layer 121 and the second semiconductor layer 123. The emission layer 122 may receive holes and electrons from the first semiconductor layer 121 and the second semiconductor layer 123 to emit light. The emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed on the first semiconductor layer 121. The first electrode 124 is an electrode for electrically connecting the first connection electrode CE1 and the first semiconductor layer 121. The first electrode 124 may be disposed on a top surface of the first semiconductor layer 121 exposed from the emission layer 122 and the second semiconductor layer 123. Meanwhile, FIG. 3 illustrates that two first electrodes 124 are disposed on a top surface of the first semiconductor layer 121, but is not limited thereto. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 may be disposed on the top surface of the second semiconductor layer 123. The second electrode 125 is an electrode which electrically connects the second connection electrode CE2 and the second semiconductor layer 123. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The encapsulation layer 126 is disposed to enclose the first semiconductor layer 121, the emission layer 122, the second semiconductor layer 123, the first electrode 124, and the second electrode 125. The encapsulation layer 126 may be formed of an insulating material to protect the first semiconductor layer 121, the emission layer 122, and the second semiconductor layer 123. The encapsulation layer 126 may be disposed to cover a side surface and a top surface of the first semiconductor layer 121, a side surface of the emission layer 122, a side surface and a top surface of the second semiconductor layer 123, the first electrode 124 and the second electrode 125. A contact hole which exposes the first electrode 124 and the second electrode 125 is formed in the encapsulation layer 126 to electrically connect the first connection electrode CE1 and the second connection electrode CE2 to the first electrode 124 and the second electrode 125, respectively.

The encapsulation layer 126 may be formed of a transparent insulating material, and for example, may be configured by a single layer or a double layer of silicon oxide (SiOx) or silicon nitride (SiNx), but is not limited thereto.

The second insulating layer 112 is disposed on the light emitting element LED and the first insulating layer 111. The second insulating layer 112 may be disposed to cover the first insulating layer 111 and the light emitting element LED. The second insulating layer 112 is disposed to cover the light emitting element LED to fix and protect the light emitting element LED. The second insulating layer 112 may be configured as a single layer or multilayer made of an organic insulating material, for example, benzocyclobutene or an acrylic-based organic material, but is not limited thereto.

The first connection electrode CE1 is disposed in each of the plurality of sub pixels SP on the second insulating layer 112. The first connection electrode CE1 is an electrode for electrically connecting the light emitting element LED and the first assembly line AL1. For example, the first connection electrode CE1 may be connected to any one of the plurality of first electrodes of the light emitting element LED through a contact hole formed in the second insulating layer 112. The first connection electrode CE1 may be connected to the first assembly line AL1 through contact holes formed in the second insulating layer 112 and the first insulating layer 111. Accordingly, the first electrode and the first semiconductor layer of the light emitting element LED may be electrically connected to the first assembly line AL1 through the first connection electrode CE1.

The second connection electrode CE2 may be disposed on the second insulating layer 112 and spaced apart from the first connection electrode CE1 in each of the plurality of sub pixels SP. The second connection electrode CE2 is an electrode for electrically connecting the light emitting element LED and the second assembly line AL2. The second connection electrode CE2 may be connected to the second electrode of the light emitting element LED through a contact hole formed in the second insulating layer 112. The second connection electrode CE2 may be connected to the second assembly line AL2 through contact holes formed in the second insulating layer 112 and the first insulating layer 111. Accordingly, the second electrode and the second semiconductor layer of the light emitting element LED may be electrically connected to the second assembly line AL2 through the second connection electrode CE2.

The first connection electrode CE1 and the second connection electrode CE2 may be formed of a transparent conductive material to allow light emitted from the light emitting element LED to propagate toward the upper side of the substrate 110. For example, the first connection electrode CE1 and the second connection electrode CE2 may be made of a transparent conductive material, such as indium tin oxide (ITO) or indium zinc oxide (IZO), but are not limited thereto.

Referring to FIG. 3, a plurality of pockets PC may be disposed in an area between the first assembly electrode AE1 and the second assembly electrode AE2. The center of the pocket PC may correspond to a center area between the first assembly electrode AE1 and the second assembly electrode AE2.

The pocket PC may have a width greater than the maximum width of the light emitting element LED so that the light emitting element LED is seated in the pocket PC. Since the pocket PC has a larger size than the light emitting element LED, the light emitting element LED self-assembled in the pocket PC may be disposed on the first assembly electrode AE1 and the second assembly electrode AE2 without interference with the pocket PC.

On the other hand, the dielectrophoresis force is concentrated on the edge of the assembly electrode. Accordingly, when the edge of the assembly electrode does not overlap the pocket, the light emitting element is assembled in an unstable state in the pocket, so that the fixing of the light emitting element is unstable or the electrical contact between the light emitting element and the connection electrode may be degraded. Further, when the light emitting element is assembled in the pocket, the assembled light emitting element is biased toward one side in which the corner side of the assembly electrode is disposed so that a problem may arise where another light emitting element is seated in the space between the light emitting element formed on the other side and the pocket.

Accordingly, in the display device 100 according to one or more embodiments of the present disclosure, the plurality of pockets PC overlap the vertices of the plurality of first assembly electrodes AE1 and the vertices of the plurality of second assembly electrodes AE2. Accordingly, since an area in which the dielectrophoresis force is most strongly generated is located in the plurality of pockets PC, the plurality of light emitting elements LED may be stably assembled and fixed in the plurality of pockets PC.

At this time, as the plurality of light emitting elements LED is assembled to be positioned in the plurality of pockets PC, a space in which the other light emitting element LED is to be assembled may not be formed in one pocket PC in which one light emitting element LED is assembled. Accordingly, only one light emitting element LED is assembled in one pocket PC to improve the assembly yield of the plurality of light emitting elements LED and implement process optimization.

As described above, since the dielectrophoresis force is concentrated on the corner portion of the assembly electrode AE, as the electric field force applied between the first assembly electrode AE1 and the second assembly electrode AE2 positioned to be spaced apart from each other is not dispersed, the plurality of light emitting elements LED may be stably fixed without overlapping one by one in the plurality of pockets PC. To this end, it is preferable that the plurality of pockets PC overlap the vertices of the plurality of first assembly electrodes AE1 and the vertices of the plurality of second assembly electrodes AE2, and that there are one vertex of the first assembly electrode AE1 and one vertex of the plurality of second assembly electrodes AE2 overlapping in the pocket PC, respectively. The vertices of the first assembly electrode AE1 and the vertices of the plurality of second assembly electrodes AE2 overlapping in the pocket PC may be spaced apart from each other so as to be located opposite to each other with respect to the major axis of the pocket PC having an oval planar shape. That is, the vertices of the first assembly electrode AE1 and the vertices of the plurality of second assembly electrodes AE2 overlapping in the pocket PC may be spaced apart from each other along the major axis of the second pocket PC2 and the major axis of the third pocket PC3.

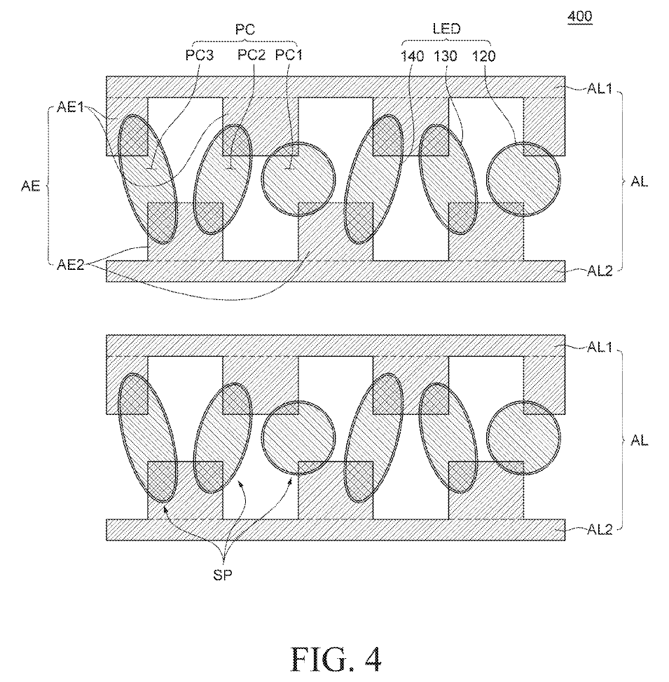

FIG. 4 is an enlarged plan view of a display device according to one or more other embodiments of the present disclosure. A display device 400 of FIG. 4 is substantially identical in configuration to the display device 100 of FIGS. 1-3, except for a plurality of pockets PC and a plurality of assembly electrodes AE. Therefore, repeated descriptions of the identical components will be omitted.

Referring to FIG. 4, a plurality of first assembly electrodes AE1 and a plurality of second assembly electrodes AE2 for self-assembling the plurality of light emitting elements LED are disposed.

Widths of the plurality of first assembly electrodes AE1 and the plurality of second assembly electrodes AE2 may be the same. For example, a planar shape of each of the plurality of first assembly electrodes AE1 and a planar shape of each of the plurality of second assembly electrodes AE2 may be a rectangle.

Each of the plurality of first assembly electrodes AE1 may be disposed to be staggered from the plurality of second assembly electrodes AE2 in a row direction and a column direction, and each of the plurality of second assembly electrodes AE2 may be disposed to be staggered from the plurality of first assembly electrodes AE1 in a row direction and a column direction. For example, each of the plurality of first assembly electrodes AE1 may be correspondingly disposed between the plurality of second assembly electrodes AE2, and each of the plurality of second assembly electrodes AE2 may be correspondingly disposed between the plurality of first assembly electrodes AE1.

In this case, the edge of the first assembly electrode AE1 and the edge of the second assembly electrode AE2 may be disposed on the same plane. Accordingly, the vertex of the first assembly electrode AE1 and the vertex of the second assembly electrode AE2 may face each other on the same line. However, the present disclosure is not limited thereto, and the vertex of the first assembly electrode AE1 and the vertex of the second assembly electrode AE2 may be disposed on different lines. For example, a vertex of the second assembly electrode AE2 may be disposed between the vertices of the adjacent first assembly electrode AE1, and a vertex of the first assembly electrode AE1 may be disposed between the vertices of the adjacent second assembly electrode AE2.

A plurality of pockets PC may be disposed to overlap the vertices of the plurality of first assembly electrodes AE1 and the vertices of the plurality of second assembly electrodes AE2. Therefore, one first assembly electrode AE1 of the plurality of first assembly electrodes AE1 may overlap a part of two adjacent pockets PC among the plurality of pockets PC, and one second assembly electrode AE2 of the plurality of second assembly electrodes AE2 may overlap a part of two adjacent pockets PC among the plurality of pockets PC. For example, one first assembly electrode AE1 may overlap a part of the first pocket PC1 and a part of the second pocket PC2, another first assembly electrode AE1 may overlap a part of the second pocket PC2 and a part of the third pocket PC3, and the other first assembly electrode AE1 may overlap a part of the first pocket PC1 and a part of the third pocket PC3. In addition, one second assembly electrode AE2 may overlap a part of the first pocket PC1 and a part of the second pocket PC2, another second assembly electrode AE2 may overlap a part of the second pocket PC2 and a part of the third pocket PC3, and the other second assembly electrode AE2 may overlap a part of the first pocket PC1 and a part of the third pocket PC3.

Referring to FIG. 4, the first pocket PC1, the second pocket PC2, and the third pocket PC3 may be sequentially disposed along a direction in which the first assembly line AL1 and the second assembly line AL2 extend.

The major axis direction of the second pocket PC2 and the third pocket PC3 may be disposed in a diagonal direction with a direction in which the plurality of assembly electrodes AE extends. In this case, a major axis direction of the second pocket PC2 and a major axis direction of the third pocket PC3 may be different from each other. For example, the major axis direction of the second pocket PC2 may intersect the major axis direction of the third pocket PC3.

Meanwhile, when the plurality of pockets PC is configured by a first pocket PC1, a second pocket PC2, and a third pocket PC3, major axis directions of adjacent second pockets PC2 may intersect each other, and major axis directions of adjacent third pockets PC3 may intersect each other. However, the present disclosure is not limited thereto. When the plurality of pockets PC further includes a fourth pocket, the major axis directions of the adjacent second pockets PC2 may be parallel to each other, and the major axis directions of the adjacent third pockets PC3 may be parallel to each other.

The light emitting element LED is disposed in each of the plurality of pockets PC.

In the display device 400 according to one or more other embodiments of the present disclosure, the plurality of pockets PC overlap vertices of the plurality of first assembly electrodes AE1 and vertices of the plurality of second assembly electrodes AE2. Accordingly, since an area in which the dielectrophoresis force is most strongly generated is located in the plurality of pockets PC, the plurality of light emitting elements LED may be stably assembled and fixed in the plurality of pockets PC, and only one light emitting element LED may be assembled in one pocket PC. Accordingly, the assembly yield of the light emitting element LED is improved and process optimization may be implemented.

In the display device 400 according to one or more other embodiments of the present disclosure, the number of light emitting elements LED that may be assembled using the polygonal assembly electrode AE may be increased. For example, when the planar shape of the assembly electrode AE is a quadrangular shape, two pockets PC overlapping the vertex of the first assembly electrode AE1 and overlapping the vertex of the second assembly electrode AE2 may be disposed on one first assembly electrode AE1 and one second assembly electrode AE2. Accordingly, in the display device 400 according to one or more other embodiments of the present disclosure, the number of light emitting elements LED that may be assembled using a pair of assembly electrodes AE may be increased. Accordingly, the assembly resolution of the plurality of light emitting elements LED may increase, and the degree of integration may increase.

In the display device 400 according to one or more other embodiments of the present disclosure, the major axis direction of the second pocket PC2 and the third pocket PC3 having an oval planar shape are disposed in a direction in which the plurality of assembly electrodes AE extends and a diagonal direction to stably assemble and fix the plurality of light emitting elements LED in the plurality of pockets PC. The dielectrophoresis force may be strongly formed in an oblique direction at the corners of the plurality of assembly electrodes AE. Therefore, in the display device 400 according to one or more other embodiments of the present disclosure, the major axis direction of the second pocket PC2 and the third pocket PC3 may be disposed in a diagonal direction of the assembly electrode AE having a strong dielectrophoresis force, thereby improving the assembly yield of the plurality of light emitting elements LED.

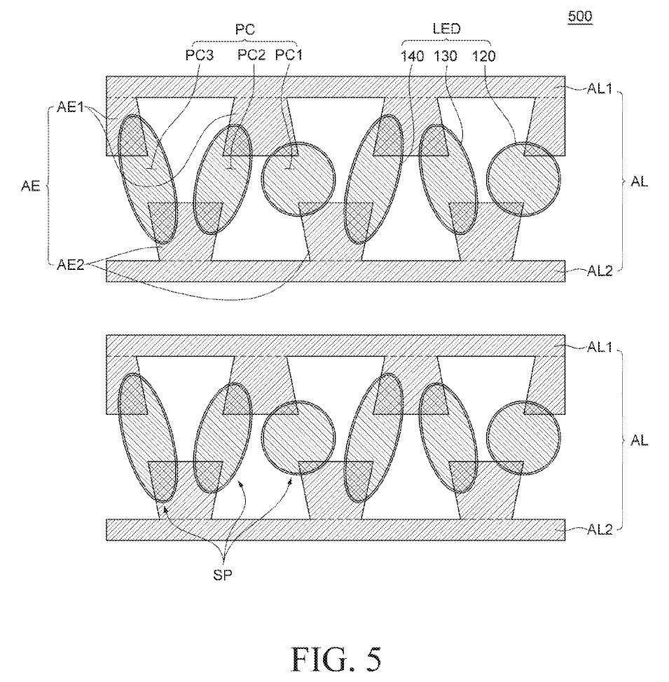

FIG. 5 is an enlarged plan view of a display device according to still one or more other embodiments of the present disclosure. A display device 500 of FIG. 5 is substantially identical in configuration to the display device 400 of FIG. 4, except for a plurality of assembly electrodes AE. Therefore, repeated descriptions of the identical components will be omitted.

Referring to FIG. 5, a plurality of first assembly electrodes AE1 and a plurality of second assembly electrodes AE2 for self-assembling the plurality of light emitting elements LED are disposed.

The widths of the plurality of first assembly electrodes AE1 and the widths of the plurality of second assembly electrodes AE2 may be gradually changed. Specifically, the width of the plurality of second assembly electrodes AE2 increases as they approach the plurality of first assembly electrodes AE1. The width of the plurality of first assembly electrodes AE1 increases as they approach the plurality of second assembly electrodesAE2. For example, planar shapes of the plurality of first assembly electrodes AE1 and the plurality of second assembly electrodes AE2 may be trapezoidal.

Referring to FIG. 5, a plurality of pockets PC may be disposed so as to overlap the vertices of the plurality of first assembly electrodes AE1 and the vertices of the plurality of second assembly electrodes AE2.

In the display device 500 according to still one or more other embodiments of the present disclosure, the plurality of pockets PC overlap the vertices of the plurality of first assembly electrodes AE1 and the vertices of the plurality of second assembly electrodes AE2. Accordingly, since an area in which the dielectrophoresis force is most strongly generated is located in the plurality of pockets PC, the plurality of light emitting elements LED may be stably assembled and fixed in the plurality of pockets PC, and only one light emitting element LED may be assembled in one pocket PC. Accordingly, the assembly yield of the light emitting element LED is improved and process optimization may be implemented.

In the display device 500 according to still one or more other embodiments of the present disclosure, the number of light emitting elements LED that may be assembled using the polygonal assembly electrode AE may be increased, thereby increasing the assembly resolution.

In the display device 500 according to still one or more other embodiments of the present disclosure, the major axis direction of the second pocket PC2 and the third pocket PC3 may be disposed in a diagonal direction of the assembly electrode AE in which a dielectrophoresis force is strongly generated, thereby improving the assembly yield of the plurality of light emitting elements LED.

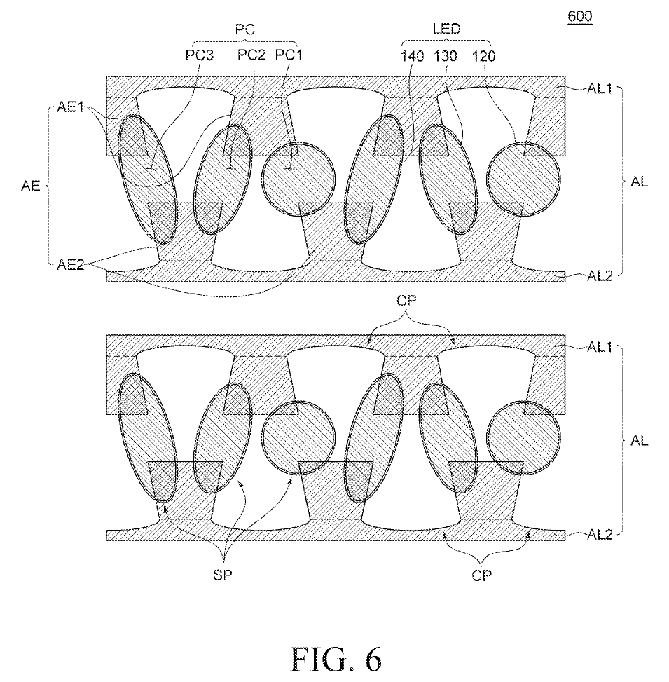

FIG. 6 is an enlarged plan view of a display device according to still one or more other embodiments of the present disclosure. A display device 600 of FIG. 6 is substantially identical in configuration to the display device 500 of FIG. 5, except for a plurality of assembly lines AL. Therefore, repeated descriptions of the identical components will be omitted.

A plurality of assembly lines AL connected to the plurality of assembly electrodes AE is disposed. For example, the plurality of first assembly electrodes AE1 may be connected to the plurality of first assembly lines AL1 and the plurality of second assembly electrodes AE2 may be connected to the plurality of second assembly lines AL2.

Referring to FIG. 6, an edge of each of the plurality of assembly lines AL may include a plurality of concave portions CP. For example, the edges of the plurality of first assembly lines AL1 and the edges of the plurality of second assembly lines AL2 may include a plurality of concave portions CP.

The plurality of concave portions CP of the plurality of first assembly lines AL1 may be disposed at edges of the plurality of first assembly lines AL1 facing the plurality of second assembly lines AL2, and the plurality of concave portions CP of the plurality of second assembly lines AL2 may be disposed at edges of the plurality of second assembly lines AL2 facing the plurality of first assembly lines AL1.

Meanwhile, the concave portion CP of the first assembly line AL1 may face the second assembly electrode AE2, and the concave portion CP of the second assembly line AL2 may face the first assembly electrode AE1. Therefore, the concave portion CP of the first assembly line AL1 and the concave portion CP of the second assembly line AL2 may be disposed to be staggered in the row direction and the column direction, but are not limited thereto.

Further, the plurality of concave portions CP may be alternately disposed with the plurality of assembly electrodes AE. For example, the concave portion CP of the first assembly line AL1 may be disposed between the first assembly electrodes AE1, and the plurality of concave portions CP of the second assembly line AL2 may be disposed between the second assembly electrodes AE2.

In addition, the concave portion CP of the first assembly line AL1 and the concave portion CP of the second assembly line AL2 may be disposed between adjacent pockets PC.

In the display device 600 according to still one or more other embodiments of the present disclosure, the plurality of pockets PC overlap the vertices of the plurality of first assembly electrodes AE1 and the vertices of the plurality of second assembly electrodes AE2. Accordingly, since an area in which the dielectrophoresis force is most strongly generated is located in the plurality of pockets PC, the plurality of light emitting elements LED may be stably assembled and fixed in the plurality of pockets PC, and only one light emitting element LED may be assembled in one pocket PC. Accordingly, the assembly yield of the light emitting element LED is improved and process optimization may be implemented.

In the display device 600 according to still one or more other embodiments of the present disclosure, the number of light emitting elements LED that may be assembled using the polygonal assembly electrode AE may be increased, thereby increasing the assembly resolution.

In the display device 600 according to still one or more other embodiments of the present disclosure, the major axis direction of the second pocket PC2 and the third pocket PC3 may be disposed in a diagonal direction of the assembly electrode AE in which a dielectrophoresis force is strongly generated, thereby improving the assembly yield of the plurality of light emitting elements LED.

In the display device 600 according to still one or more other embodiments of the present disclosure, the plurality of first assembly lines AL1 includes a plurality of concave portions CP facing the plurality of second assembly electrodes AE2, and the plurality of second assembly lines AL2 includes a plurality of concave portions CP facing the plurality of first assembly electrodes AE1 to increase the relative magnitude of dielectrophoresis formed in the plurality of pockets PC. For example, as the distance between the plurality of second assembly electrodes AE2 and the plurality of first assembly lines AL1 increases in the non-overlapping area with the plurality of pockets PC, and the distance between the plurality of first assembly electrodes AE1 and the plurality of second assembly lines AL2 increases, the dielectrophoresis force formed outside the plurality of pockets PC may decrease. On the other hand, the relative dielectrophoresis force formed in the plurality of pockets PC may increase. That is, as the distance between the plurality of assembly electrodes AE and the plurality of assembly lines AL increases in the non-overlapping area with the plurality of pockets PC, the relative dielectrophoresis force formed in the plurality of pockets PC may increase. Accordingly, in the display device 600 according to still one or more other embodiments of the present disclosure, the plurality of assembly lines AL including the plurality of concave portions CP is disposed to strongly form a relative dielectrophoretic force formed in the plurality of pockets PC and improve the assembly yield of the plurality of light emitting elements LED.

The embodiments of the present disclosure can also be described as follows:

According to one or more embodiments of the present disclosure, a display device includes a substrate on which a plurality of sub pixels is defined, a plurality of first assembly electrodes and a plurality of second assembly electrodes disposed in each of the plurality of sub pixels, the plurality of second assembly electrodes are disposed to be spaced apart from the plurality of first assembly electrodes, a first insulating layer disposed on the plurality of first assembly electrodes and the plurality of second assembly electrodes and including a plurality of pockets overlapping the plurality of sub pixels, and a plurality of light emitting elements disposed in the plurality of pockets of the first insulating layer, each of the plurality of pockets overlaps a vertex of the plurality of first assembly electrodes and a vertex of the plurality of second assembly electrodes.

According to one or more other embodiments of the present disclosure, one pocket of the plurality of pockets may overlap one vertex of the vertices of the plurality of first assembly electrodes and one vertex of the vertices of the plurality of second assembly electrodes.

According to yet one or more other embodiments of the present disclosure, the plurality of pockets may include a plurality of oval pockets having an oval planar shape, and the vertices of the plurality of first assembly electrodes and the vertices of the plurality of second assembly electrodes may be spaced apart from each other along the major axis direction of the plurality of oval pockets.

According to yet one or more other embodiments of the present disclosure, planar shape of each of the plurality of first assembly electrodes and the plurality of second assembly electrodes is a triangle, and the plurality of first assembly electrodes and the plurality of second assembly electrodes may be disposed to face each other.

According to yet one or more other embodiments of the present disclosure, the plurality of pockets may include a plurality of oval pockets having an oval planar shape, and major axes of the plurality of oval pockets may be disposed in parallel to each other.

According to yet one or more other embodiments of the present disclosure, each of the plurality of first assembly electrodes may be correspondingly disposed between the plurality of second assembly electrodes.

According to yet one or more other embodiments of the present disclosure, a planar shape of each of the plurality of first assembly electrodes and the plurality of second assembly electrodes may be a trapezoidal shape.

According to yet one or more other embodiments of the present disclosure, one first assembly electrode of the plurality of first assembly electrodes may overlap a part of two adjacent pockets among the plurality of pockets, and one second assembly electrode of the plurality of second assembly electrodes may overlap a part of two adjacent pockets among the plurality of pockets.

According to yet one or more other embodiments of the present disclosure, the plurality of pockets may include a plurality of oval pockets having an oval planar shape, and major axes of adjacent oval pockets among the plurality of oval pockets may be disposed in directions crossing each other.

According to yet one or more other embodiments of the present disclosure, the display device may further include a plurality of first assembly lines connected to the plurality of first assembly electrodes and a plurality of second assembly lines connected to the plurality of second assembly electrodes. The plurality of first assembly lines may include a plurality of concave portions disposed in a direction facing the plurality of second assembly electrodes, and the plurality of second assembly lines may include a plurality of concave portions disposed in a direction facing the plurality of first assembly electrodes.

A display device according to one or more other embodiments of the present disclosure includes a substrate on which a plurality of sub pixels are defined, a plurality of first assembly electrodes and a plurality of second assembly electrodes disposed in each of the plurality of sub pixels, the plurality of second assembly electrodes are disposed to be spaced apart from the plurality of first assembly electrodes, a first insulating layer disposed on the plurality of first assembly electrodes and the plurality of second assembly electrodes and including a plurality of pockets overlapping the plurality of sub pixels, and a plurality of light emitting elements disposed within the plurality of pockets of the first insulating layer, wherein a planar shape of each of the plurality of pockets surrounds one vertex of the vertices of the plurality of first assembly electrodes and one vertex of the vertices of the plurality of second assembly electrodes.

According to one or more other embodiments of the present disclosure, the widths of the plurality of first assembly electrodes and the widths of the plurality of second assembly electrodes may gradually change.

According to yet one or more other embodiments of the present disclosure, the width of the plurality of second assembly electrodes may decrease as they approach the plurality of first assembly electrodes and the width of the plurality of first assembly electrodes may decrease as they approach the plurality of second assembly electrodes.

According to yet one or more other embodiments of the present disclosure, the width of the plurality of second assembly electrodes may increase as they approach the plurality of first assembly electrodes, and the width of the plurality of first assembly electrodes may increase as they approach the plurality of second assembly electrodes.

According to yet one or more other embodiments of the present disclosure, the plurality of first assembly electrodes may be disposed in the same column as the plurality of second assembly electrodes.

According to yet one or more other embodiments of the present disclosure, each of the plurality of first assembly electrodes may be disposed to be staggered from the plurality of second assembly electrodes in a row direction and a column direction.

According to yet one or more other embodiments of the present disclosure, the display device may further include a plurality of first assembly lines connected to the plurality of first assembly electrodes, and a plurality of second assembly lines connected to the plurality of second assembly electrodes. The plurality of first assembly lines may include a plurality of concave portions disposed at edges facing the plurality of second assembly lines, and the plurality of second assembly lines may include a plurality of concave portions disposed at edges facing the plurality of first assembly lines.

According to yet one or more other embodiments of the present disclosure, the plurality of concave portions of the plurality of first assembly lines may be disposed between the plurality of first assembly electrodes, and the plurality of concave portions of the plurality of second assembly lines may be disposed between the plurality of second assembly electrodes.

A display device according to one or more other embodiments of the present disclosure includes a substrate on which a plurality of sub pixels is defined, a first assembly line and a second assembly line disposed to be spaced apart from each other by a predetermined interval in a row of sub pixels or a column of sub pixels, a plurality of first assembly electrodes connected to the first assembly line, a plurality of second assembly electrodes connected to the second assembly line, the plurality of second assembly electrodes being spaced apart from the plurality of first assembly electrodes, a first insulating layer disposed on the plurality of first assembly electrodes and the plurality of second assembly electrodes and including a plurality of pockets, and a plurality of light emitting elements respectively disposed in the plurality of pockets, each of the plurality of pockets overlaps a vertex of one first assembly electrode and a vertex of one corresponding second assembly electrode.

According to one or more other embodiments of the present disclosure, the plurality of first assembly electrodes may extend from the first assembly line toward the second assembly line, and the plurality of second assembly electrodes may extend from the second assembly line toward the first assembly line

Although the embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure.

What is claimed is:

1. A display device, comprising:
a substrate on which a plurality of sub pixels is defined;
a plurality of first assembly electrodes and a plurality of second assembly electrodes disposed in each of the plurality of sub pixels, the plurality of second assembly electrodes being disposed to be spaced apart from the plurality of first assembly electrodes;
a first insulating layer disposed on the plurality of first assembly electrodes and the plurality of second assembly electrodes, the first insulating layer including a plurality of pockets overlapping the plurality of sub pixels; and
a plurality of light emitting elements disposed in the plurality of pockets of the first insulating layer,
wherein each of the plurality of pockets overlaps a vertex of the plurality of first assembly electrodes and a vertex of the plurality of second assembly electrodes.

2. The display device according to claim 1, wherein one pocket of the plurality of pockets overlaps one vertex of a first plurality of vertices of the plurality of first assembly electrodes and one vertex of a second plurality of vertices of the plurality of second assembly electrodes.

3. The display device according to claim 1, wherein the plurality of pockets include a plurality of oval pockets having an oval planar shape, and
wherein a first plurality of vertices of the plurality of first assembly electrodes and a second plurality of vertices of the plurality of second assembly electrodes are spaced apart from each other along a major axis direction of the plurality of oval pockets.

4. The display device according to claim 1, wherein a planar shape of each of the plurality of first assembly electrodes and the plurality of second assembly electrodes is a triangle, and wherein the plurality of first assembly electrodes and the plurality of second assembly electrodes are disposed to face each other.

5. The display device according to claim 1, wherein the plurality of pockets includes a plurality of oval pockets having an oval planar shape, and
wherein major axes of the plurality of oval pockets are disposed in parallel to each other.

6. The display device according to claim 1, wherein each of the plurality of first assembly electrodes is correspondingly disposed between the plurality of second assembly electrodes.

7. The display device according to claim 6, wherein a planar shape of each of the plurality of first assembly electrodes and the plurality of second assembly electrodes is a trapezoidal shape.

8. The display device according to claim 1, wherein one first assembly electrode of the plurality of first assembly electrodes overlaps a part of two adjacent pockets among the plurality of pockets, and
wherein one second assembly electrode of the plurality of second assembly electrodes overlaps a part of two adjacent pockets among the plurality of pockets.

9. The display device according to claim 1, wherein the plurality of pockets includes a plurality of oval pockets having an oval planar shape, and
wherein major axes of adjacent oval pockets among the plurality of oval pockets are disposed in directions intersecting each other.

10. The display device according to claim 1, further comprising:
a plurality of first assembly lines connected to the plurality of first assembly electrodes; and
a plurality of second assembly lines connected to the plurality of second assembly electrodes,
wherein the plurality of first assembly lines includes a plurality of concave portions disposed in a direction facing the plurality of second assembly electrodes, and
the plurality of second assembly lines includes a plurality of concave portions disposed in a direction facing the plurality of first assembly electrodes.

11. A display device, comprising:
a substrate on which a plurality of sub pixels is defined;
a plurality of first assembly electrodes and a plurality of second assembly electrodes disposed in each of the plurality of sub pixels, the plurality of second assembly electrodes being disposed to be spaced apart from the plurality of first assembly electrodes;
a first insulating layer disposed on the plurality of first assembly electrodes and the plurality of second assembly electrodes, the first insulating layer including a plurality of pockets overlapping the plurality of sub pixels; and
a plurality of light emitting elements disposed in the plurality of pockets of the first insulating layer,
wherein a planar shape of each of the plurality of pockets encloses one vertex of a first plurality of vertices of the plurality of first assembly electrodes and one vertex of a second plurality of vertices of the plurality of second assembly electrodes.

12. The display device according to claim 11, wherein widths of the plurality of first assembly electrodes and widths of the plurality of second assembly electrodes gradually change.

13. The display device according to claim 12, wherein the widths of the plurality of second assembly electrodes decrease as second assembly electrodes of the plurality of second assembly electrodes approach the plurality of first assembly electrodes, and
wherein the widths of the plurality of first assembly electrodes decrease as first assembly electrodes of the plurality of first assembly electrodes approach the plurality of second assembly electrodes.

14. The display device according to claim 12, wherein the widths of the plurality of second assembly electrodes increase as second assembly electrodes of the plurality of second assembly electrodes approach the plurality of first assembly electrodes, and
wherein widths of the plurality of first assembly electrodes increase as first assembly electrodes of the plurality of first assembly electrodes approach the plurality of second assembly electrodes.

15. The display device according to claim 11, wherein the plurality of first assembly electrodes is disposed in a same column as the plurality of second assembly electrodes.

16. The display device according to claim 11, wherein each of the plurality of first assembly electrodes is disposed to be staggered from the plurality of second assembly electrodes in a row direction and a column direction.

17. The display device according to claim 11, further comprising:
a plurality of first assembly lines connected to the plurality of first assembly electrodes; and
a plurality of second assembly lines connected to the plurality of second assembly electrodes,
wherein the plurality of first assembly lines includes a plurality of concave portions disposed at edges facing the plurality of second assembly lines, and
wherein the plurality of second assembly lines includes a plurality of concave portions disposed at edges facing the plurality of first assembly lines.

18. The display device according to claim 17, wherein the plurality of concave portions of the plurality of first assembly lines is disposed between the plurality of first assembly electrodes, and
wherein the plurality of concave portions of the plurality of second assembly lines is disposed between the plurality of second assembly electrodes.

19. A display device, comprising:
a substrate on which a plurality of sub pixels is defined;
a first assembly line and a second assembly line disposed to be spaced apart from each other by a predetermined interval in a row of sub pixels of the plurality of sub pixels or a column of sub pixels of the plurality of sub pixels;
a plurality of first assembly electrodes connected to the first assembly line;
a plurality of second assembly electrodes connected to the second assembly line, the plurality of second assembly electrodes being spaced apart from the plurality of first assembly electrodes;
a first insulating layer disposed on the plurality of first assembly electrodes and the plurality of second assembly electrodes, the first insulating layer comprising a plurality of pockets; and
a plurality of light emitting elements respectively disposed in the plurality of pockets,
wherein each of the plurality of pockets overlaps a vertex of one first assembly electrode of the plurality of first assembly electrodes and a vertex of one corresponding second assembly electrode of the plurality of second assembly electrodes.

20. The display device according to claim 19, wherein the plurality of first assembly electrodes extends from the first assembly line toward the second assembly line, and
wherein the plurality of second assembly electrodes extends from the second assembly line toward the first assembly line.
